(19) United States
(12) Patent Application Publication
(10) Pub. No.: US 2008/0305613 A1
(43) Pub. Date: Dec. 11, 2008

(54) METHOD FOR FABRICATING AN SOI DEFINED SEMICONDUCTOR DEVICE

(75) Inventors: Mario M. PELELLA, Mountain View, CA (US); Darin A. CHAN, Campbell, CA (US)

Correspondence Address: INGRASSIA FISHER & LORENZ, P.C. (AMD), 7010 E. COCHISE ROAD, SCOTTSDALE, AZ, 85253, US

(73) Assignee: ADVANCED MICRO DEVICES, INC., Austin, TX (US)

(21) Appl. No.: 11/759,411

(22) Filed: Jun. 7, 2007

(51) Int. Cl. H01L 21/762

(52) U.S. Cl. 438/433; 257/E21.545

(57) ABSTRACT

Methods are provided for fabricating a semiconductor on insulator (SOI) component on a semiconductor layer/insulator/substrate structure. The method includes forming one or more shallow trench isolation (STI) regions extending through the semiconductor layer to the insulator. First and second openings are etched through the STI and the insulator using the remaining SOI material in the semiconductor layer as an etch mask. N— and P-type ions are implanted into the substrate through the openings to form to form N-doped and P-doped regions therein, such as an anode and a cathode of a semiconductor diode structure. The N-doped and P-doped regions are closely spaced and precisely aligned to each other by the SOI material in the semiconductor layer. Electrical contacts are then made to the N-doped and P-doped regions.

### TECHNICAL FIELD

The present invention generally relates to methods for fabricating semiconductor device structures, and more particularly relates to methods for fabricating semiconductor on insulator (SOI) film defined semiconductor device structures.

### BACKGROUND

Semiconductor integrated circuits (ICs) include numerous semiconductor device structures, such as interconnected complementary metal oxide semiconductor (CMOS) transistors (i.e. both P-channel and N-channel MOS transistors). Improvements in the performance of ICs can be realized by forming the semiconductor device structures in a thin layer of semiconductor material overlying an insulator layer. Such semiconductor on insulator (SOI) device structures, such as CMOS transistors, can display lower junction capacitance and higher operational speeds. With the increase in the number of semiconductor device structures in ICs, it becomes important to shrink the size of individual device structures to maintain manufacturability.

Semiconductor device structures, such as CMOS transistors, have now been designed to have feature sizes (e.g., gate electrodes) less than or equal to forty-five nanometers in width. Methods previously used to fabricate devices in the substrate of an SOI structure, however, have not be able to achieve the same minimum feature size in substrate devices as are realized in the devices formed in the thin semiconductor layer. In addition, previous methods involving etching into the SOI substrate have led to chemical mechanical polishing (CMP) dishing problems and high K dielectric insulator contamination.

Accordingly, it is desirable to provide a method for fabrication of SOI semiconductor device structures which reduces CMP dishing problems and dielectric insulator contamination. Furthermore, other desirable features and characteristics of the present invention will become apparent from the subsequent detailed description of the invention and the appended claims, taken in conjunction with the accompanying drawings and this background of the invention.

### BRIEF SUMMARY

Methods are provided for fabricating a semiconductor on insulator (SOI) component on a semiconductor layer/insulator/substrate structure. The method includes, in accordance with one embodiment, forming one or more shallow trench isolation (STI) regions extending through the semiconductor layer to the insulator. First and second openings are etched through the STI and the insulator using the remaining SOI material in the semiconductor layer as an etch mask. N— and P-type ions are implanted into the substrate through the openings to form to form N-doped and P-doped regions therein, such as an anode and a cathode of a semiconductor diode structure. The N-doped and P-doped regions are closely spaced and precisely aligned to each other by the SOI material in the semiconductor layer. Electrical contacts are then made to the N-doped and P-doped regions.

### BRIEF DESCRIPTION OF THE DRAWINGS

The present invention will hereinafter be described in conjunction with the following drawing figures, wherein like numerals denote like elements, and

FIGS. 1 to 12 schematically illustrate method steps for fabrication of a semiconductor diode structure in accordance with a first embodiment of the disclosure wherein FIGS. 1 and 3 to 11 are cross section views and FIGS. 2 and 12 are plan views illustrating such method steps; and

FIGS. 13 to 19 schematically illustrate method steps for fabrication of a semiconductor structure in accordance with an additional embodiment of the disclosure wherein FIGS. 13 to 18 are cross-section views and FIG. 19 is a plan view illustrating such method steps.

### DETAILED DESCRIPTION

The following detailed description of the invention is merely exemplary in nature and is not intended to limit the invention or the application and uses of the invention. Furthermore, there is no intention to be bound by any theory presented in the preceding background of the invention or the following detailed description of the invention.

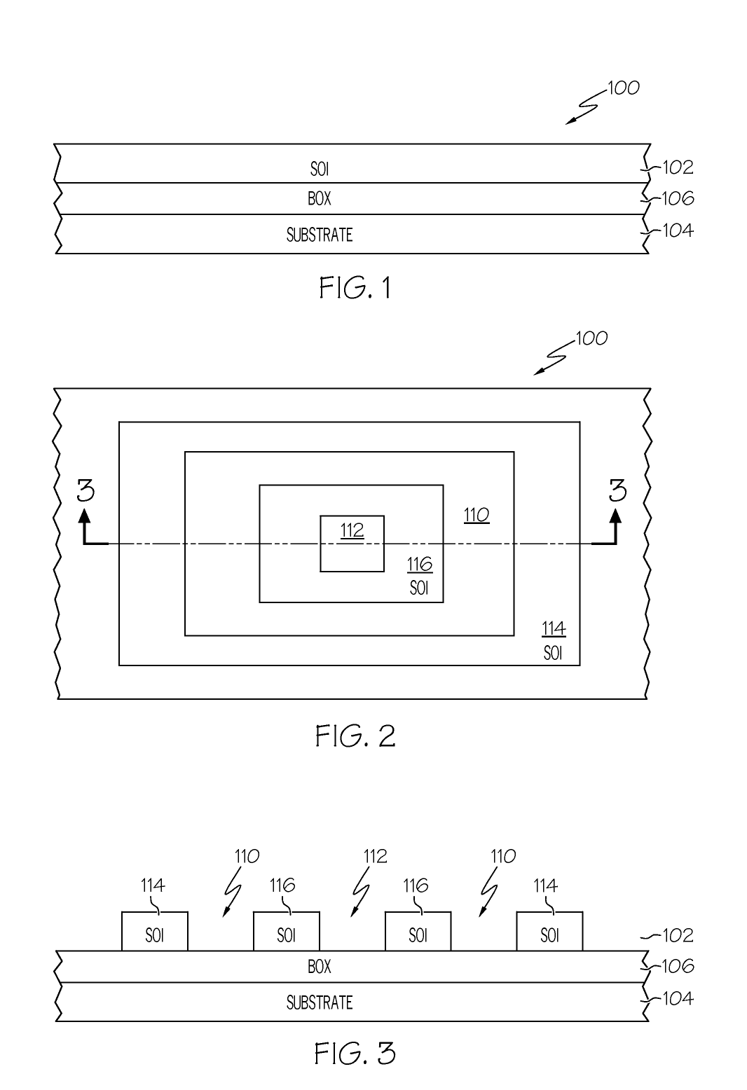

FIGS. 1 to 12 schematically illustrate method steps for the manufacture of a CMOS integrated circuit in accordance with a first embodiment of the disclosure. In these illustrative figures only a small portion or semiconductor structure 100 of the CMOS integrated circuit wherein a semiconductor diode structure is being fabricated is illustrated. Various steps in the manufacture of CMOS devices are well known and so, in the interest of brevity, many conventional steps will only be mentioned briefly herein or will be omitted entirely without providing the well known process details.

Referring to FIG. 1, the method in accordance with this embodiment of the invention begins with providing a semiconductor structure 100 including a silicon on insulator (SOI) semiconductor layer 102 and a first semiconductor layer 104 separated by an insulator layer 106. The SOI semiconductor layer 102 is a layer of SOI material, preferably a monocrystalline silicon layer. The first semiconductor layer or substrate 104 is preferably a monocrystalline silicon carrier substrate. As used herein, the terms “monocrystalline silicon layer” and “monocrystalline silicon carrier substrate” will be used to encompass the relatively pure monocrystalline silicon materials typically used in the semiconductor industry as well as silicon admixed with other elements such as germanium, carbon, and the like to form substantially monocrystalline semiconductor material.

The semiconductor structure 100 can be formed, for example, by the well known layer transfer technique. In that technique hydrogen is implanted into a subsurface region of an oxidized monocrystalline silicon wafer. The implanted wafer, i.e., the SOI substrate 102, is then flip bonded to the substrate 104. A two phase heat treatment is then carried out to split the hydrogen implanted wafer along the implanted region and to strengthen the bonding, leaving the SOI substrate 102, a thin monocrystalline silicon layer, bonded to the monocrystalline silicon substrate 104, the first semiconductor layer, and separated therefrom by the insulating layer 106, a layer of dielectric insulating material commonly referred to as a buried oxide (BOX) layer 106.

Prior to providing the semiconductor structure 100 for fabrication in accordance with the embodiment of this disclosure, the SOI substrate 102 is preferably thinned and polished, for example by chemical mechanical planarization (CMP) techniques, to a thickness of about 50-300 nanometers (nm) depending on the circuit function being implemented. Both the SOI substrate 102 and the first semiconductor layer 104 preferably have a resistivity of at least about 1-35 Ohms-centimeter. The first semiconductor layer 104 is preferably impurity doped P-type. The dielectric insulating layer 106, typically silicon dioxide, preferably has a thickness of about 50-200 nm.

Having provided the semiconductor substrate, the fabrication method in accordance with the embodiment of this disclosure continues as illustrated in FIGS. 2 and 3 by the formation of dielectric isolation regions 110, 112 extending through the SOI substrate 102 to the BOX layer 106. The dielectric isolation regions are preferably formed by the well known shallow trench isolation (STI) technique in which, as shown in FIGS. 2 and 3, trenches, such as first opening 110 and second opening 112, are etched into the SOI substrate 102 thereby removing a first and a second portion 114 of the SOI material in SOI substrate 102 to form SOI structures 116.

FIG. 2 is a plan view of the semiconductor substrate showing the first opening 110 and the second opening 112 in the SOI substrate 102. The first opening 110 etched through the SOI substrate 102 forms the inside of a first SOI ring structure 114 and the outside of a second concentric SOI ring structure 116. The second opening 112 etched through the SOI substrate 102 forms the inside of the second SOI ring structure portion of the SOI material 116, encircled by the first ring structure, wherein the first and second SOI ring structures 114, 116 are portions of the SOI material of SOI layer 102 which are not removed by the etching process. The first and second SOI ring structures 114, 116 are illustrated in FIG. 2 to be generally a rectangular shape, although those of skill in the art will understand that the ring structure can have any desired shape. FIG. 3 is a cross section view of the semiconductor substrate at the fabrication step shown in FIG. 2, the cross section view taken across line 3-3′.

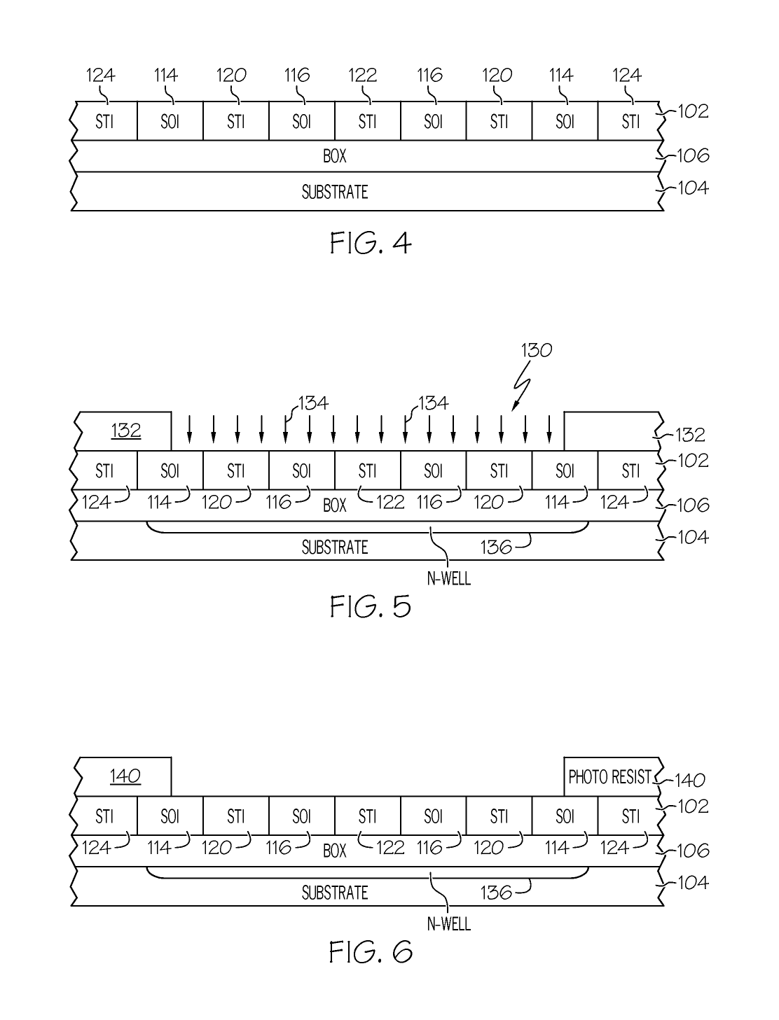

Referring to FIG. 4, the trenches 110, 112 are next filled with a dielectric material such as a deposited silicon oxide or a deposited nitride to form STI regions 120, 122 separated by the SOI pillars 116. Similarly, additional STI regions 124 are formed in the SOI substrate 102 to provide electrical isolation of the semiconductor diode structure 100 from other structures on the semiconductor IC. After the trenches 110, 112 are filled with the STI material to form STI regions 120, 122, the excess STI material is removed by CMP. Typically, when layers of material are planarized by chemical mechanical planarization (CMP) large open areas polish differently than areas that are characterized by a dense pattern of features. Those large open areas are subject to “dishing”. That is, instead of achieving a planar surface, CMP of the large open areas results in a slightly concave surface with the layer thinner at the middle of the area than at the edges. In accordance with this embodiment of the disclosure, the STI regions 120, 122 are not large open areas. Instead, the regions 120, 122 are broken up by SOI pillars 116. Inclusion of the retained SOI regions 116 avoids the dishing during CMP because the semiconductor structure being polished is now characterized by a pattern of dense SOI pillars 116.

The STI regions 120, 122 provide electrical isolation, as needed for the diode function being implemented. Additional STI region 124 provides electrical isolation of the semiconductor diode structure 100 from other structures on the semiconductor IC. Referring to FIG. 5, a mask region 130 is formed on the SOI substrate 102 by depositing a layer of photoresist on the SOI substrate 102 and patterning the photoresist to form a photoresist mask 132 which defines the mask region 130. The mask 132 is utilized as an ion implantation mask to dope the first semiconductor layer 104 by, for example, ion implantation (as indicated by the arrows 134 in FIG. 5) to deep implant ions in the first semiconductor layer 104 to form an impurity doped region 136 therein. Conductivity determining ionic impurities are implanted, as indicated by the arrows 134, into the surface of the substrate 104 to form the doped region 136. In accordance with this embodiment of the disclosure, the first semiconductor layer 104 is a p-type semiconductor substrate (i.e., doped with p-type ions) and the impurity doped region 136 is doped with n-type ions. For example, phosphorus ions can be implanted into the substrate 104 at an energy of about 200 KeV to 300 KeV and dose of about 1×10¹³ cm⁻² to 2×10¹⁴ cm⁻² to form an N-type doped region 136.

The fabrication steps depicted in FIGS. 1 to 5 occur early in the semiconductor process flow, before the polygate definition steps fabricating other portions of the integrated circuit device. The fabrication process steps in accordance with the embodiment of this disclosure do not require deposition of polysilicon or integration of a gate stack including polysilicon, metal or high-K dielectric material to form the SOI portions 114, 116, thereby, eliminating any gate stack or gate insulator contamination, particularly contamination of high-K dielectric material, such as zirconium or hafnium.

Fabrication in accordance with the embodiment of this disclosure continues later in the semiconductor IC processing, after the polysilicon gate formation steps and before the source-drain definition steps. Referring to FIG. 6, a layer 140 of photoresist is applied overlying the surface of SOI regions 114, 116 and the dielectric STI regions 120, 122 of the SOI substrate 102. The layer of photoresist 140 is patterned to form a mask region, exposing therein a portion of the SOI substrate 102 as illustrated in FIG. 6.

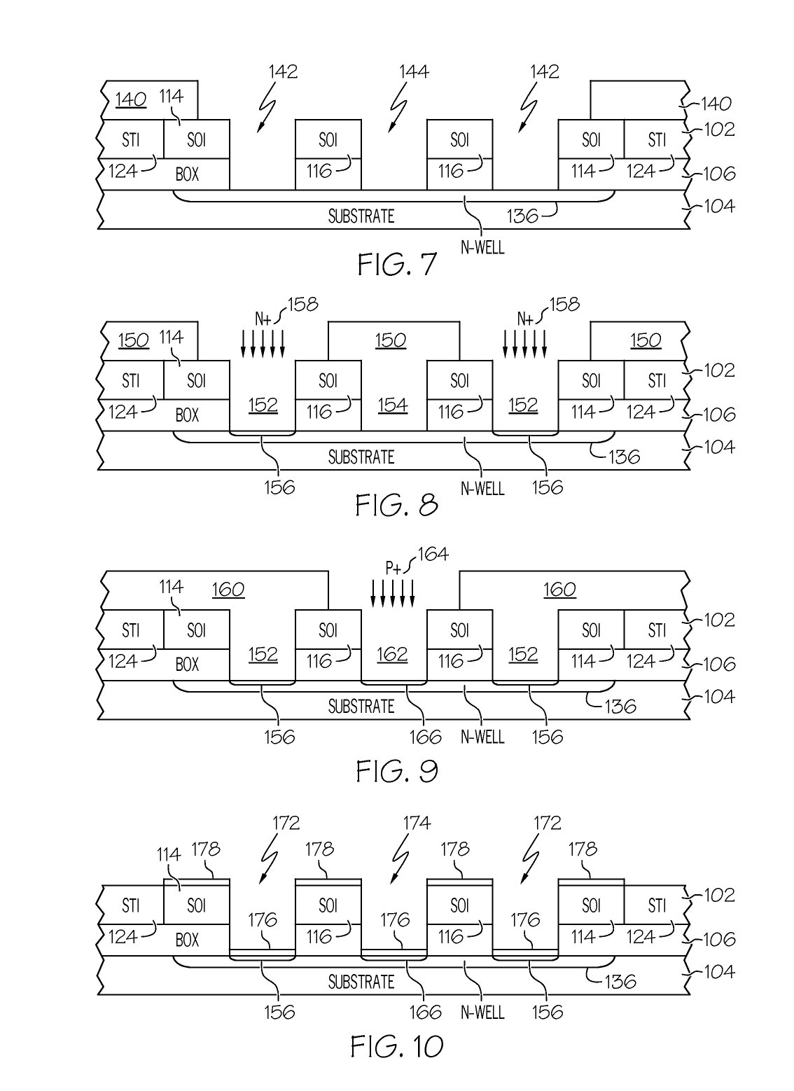

020 Referring next to FIG. 7, the layer of photoresist 140 and the two concentric rings of SOI 114, 116 are used together as an etch mask to etch openings 142 and 144 through the STI regions 120, 122 and the dielectric insulating buried oxide layer 106 to expose portions of the impurity doped region 136 of the substrate 104. Openings 142 and 144 are anisotropically etched through the STI regions 120, 122 and the buried oxide layer 106, preferably by reactive ion etching, utilizing the SOI material in the regions 114, 116 to define the openings 142 and 144. The dielectric layers (both the STI regions 120, 122 and the BOX layer 106) can be reactive ion etched, for example, using a CF₄ or CHF₃ chemistry. The spacing between openings 142, 144 as well as the total area of the diode structure 100 are determined, not by the mask opening in the photoresist 140, but by the width of the SOI regions 114, 116 and hence, in accordance with this embodiment of the disclosure, are self aligned therewith and are comparable to the minimum feature size. The spacing between the openings can thus be less than the minimum photolithographic feature spacing otherwise attainable through a cheaper, lower resolution photolithographic patterning and etching alone because the self-aligning techniques utilizing the SOI regions 114, 116 achieve smaller dimensions than can obtainable using patterned photoresist masks.

Referring to FIG. 8, after removing the photoresist layer 140 another photoresist layer 150 is applied to the structure 100 and patterned to expose ring opening 152 while masking opening 154. Patterned photoresist layer 150 is used as an ion implantation mask and N-type impurity dopant ions 156, preferably arsenic ions, are implanted into the exposed areas as indicated by arrows 158. The N-type impurity dopant ions form cathode region 156 of a substrate diode self aligned with the SOI regions 114, 116 of the SOI substrate 102 and the mask region of the photoresist layer 150.

Referring to FIG. 9, the photoresist layer 150 is removed and another photo resist layer 160 is applied to the structure 100 and is patterned to expose opening 162 while masking the previously exposed opening 152. Patterned photoresist layer 160 is used as an ion implantation mask and P-type impurity dopant ions, preferably boron ions, are implanted into the exposed areas as indicated by arrows 164. The P-type impurity dopant ions form the anode region 166 of the semiconductor diode structure 100 that are self aligned with the edge of the SOI surrounding ring 116 and the photoresist mask 160. The photoresist layer 160 is removed and both the N-type and P-type ion implanted regions are heated, preferably by rapid thermal annealing, to activate the implanted ions.

Referring to FIG. 10, in accordance with an embodiment of the disclosure, a layer of silicide forming metal such as nickel, cobalt, titanium, palladium, or the like is then deposited onto the structure 100 and in contact with the ion implanted anode and cathode regions 156, 166. The silicide forming metal preferably has a thickness of about 5 nm to 15 nm. The silicide forming metal is heated, preferably to a temperature of about 350° C. to 500° C., to cause the metal to react with the silicon with which it is in contact to form a metal silicide contact region 176 at the surface of each of the ion implanted regions 156, 166 as illustrated in FIG. 10. Silicide 178 also forms on the surface of the SOI regions 114, 116. The metal that is not in contact with silicon, for example the metal that is deposited on the STI regions 124, does not react to form a silicide during the heating step and can be removed, for example by wet etching in a H₂O₂/H₂SO₄ or HNO₃/HCl solution. The metal that is in contact with silicon of the SOI regions 114, 116, however, will react with the silicon to form the silicide 178 thereon. In accordance with the embodiment of this disclosure, this silicide 178 may remain even though it will not be utilized for providing a contact region.

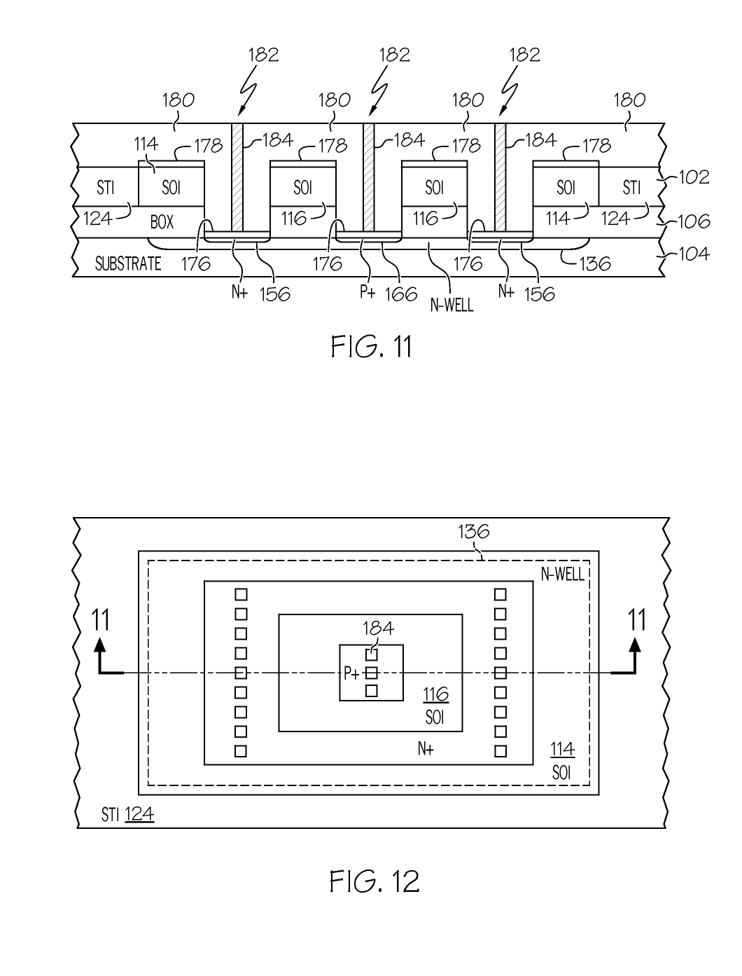

As illustrated in FIG. 11 a layer 180 of insulating interlayer dielectric (ILD) material is deposited and planarized to cover the metal silicide contact regions (as well as the silicide layers above the SOI regions 114, 116). The insulating ILD material can be deposited, for example, by low pressure chemical vapor deposition using a tetraethylorthosilicate (TEOS) source. ILD layer 180 is preferably planarized by CMP. Following the planarization, a layer of photoresist (not illustrated) is applied to the surface of the planarized insulating material and is patterned for use as an etch mask to etch contact openings 182 that extend through the insulating material to the metal silicide contact regions of the anode and cathode regions 156, 166 of the semiconductor diode structure 100.

Contact plugs 184 are formed in each of contact openings 182 to allow electrical contact to the anode and cathode regions 156, 166. The contact plugs can be formed, for example, by depositing successive layers of titanium, titanium nitride, and tungsten in known manner. The excess titanium, titanium nitride and tungsten layers can then be removed by CMP to leave contact plugs 184 as illustrated in FIG. 11.

Referring to FIG. 12, a plan view of the diode structure 100 of the semiconductor integrated circuit 100 below the ILD layer 180 is depicted. The concentric rings of the SOI regions 114, 116 separate the P-type ion doped anode region 166 from the N-type ion doped cathode region 156 and both regions 156, 166 from the STI region 124 providing electrical isolation of the semiconductor diode structure 100 from other structures on the semiconductor IC. The contacts 176 provide contact to the anode and cathode regions 166, 156. The location of the deep implanted region 136 is shown in dashed outline, as is the location of the cross section view of FIG. 11 across line 11-11′.

Those of skill in the art will appreciate that alternative and/or additional steps may be used to fabricate the semiconductor structure 100 and the order of the method steps may be changed without departing from the broad scope of the invention. For example, sidewall spacers may be formed at the edges of the anode and cathode regions 156, 166 and those spacers may be used as masks for additional ion implantations or to space the metal silicide contacts 176 apart from the sidewalls. In addition, the order of the P-type and N-type ion implantations may also be changed.

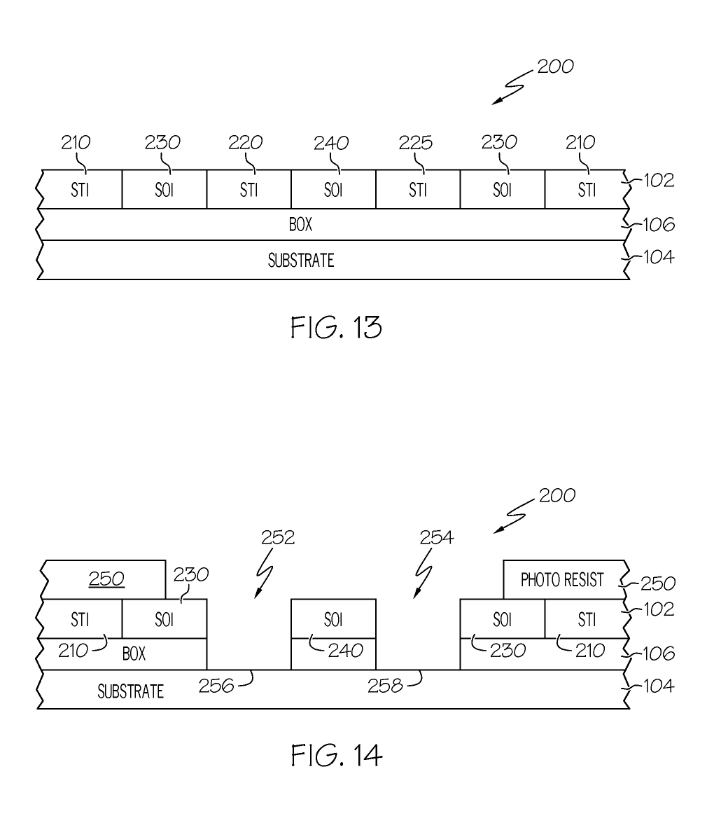

In accordance with an additional embodiment of the invention the initial step in a method for fabricating a CMOS integrated circuit structure 200 provides the semiconductor structure of FIG. 1 including the SOI substrate 102, the buried oxide insulating layer 106 and the first semiconductor substrate layer 104. The method in accordance with this additional embodiment proceeds as illustrated in the cross section view of FIG. 13. Dielectric isolation STI regions 210, 220, 225 are formed in the SOI material of substrate 102 in accordance with the well known shallow trench isolation (STI) technique to form a SOI structure 230 defining an area divided by a SOI divider 240 into a first STI region 220 and a second STI region 225, the STI region providing electrical isolation of the structure 200 from other structures on the semiconductor IC. During CMP to remove excess STI material and planarize the surface of the layer 102, the denser SOI regions 230, 240 provide support to eliminate “dishing” during CMP.

Referring to FIG. 14, processing continues by depositing a layer of photoresist 250 on the layer 102 and patterning and developing the layer of photoresist 250 to expose a portion of layer 102, including a portion of the SOI region 230 as well as STI regions 220, 225 and SOI region 240. In accordance with this alternate embodiment of the disclosure, the patterned layer of photoresist 250 and the SOI regions 230, 240 are used together as an etch mask to etch openings 252 and 254 through the dielectric STI regions 220, 225 and dielectric insulating layer 106 to expose portions 256 and 258 of the substrate 104. As in the earlier embodiment, openings 252 and 254 are anisotropically etched through the STI regions 220, 225 and the buried oxide layer 106, preferably by reactive ion etching. The spacing between the openings 252 and 254 as well as the total area of the structure 200 are determined, not by the spacing of openings in the photoresist layer 250, but by the width of the SOI divider 240 and the overall size of area defined by the SOI region 230. Thus, in accordance with this alternate embodiment of the disclosure, the openings 252, 254 are self aligned and are comparable to the minimum feature size.

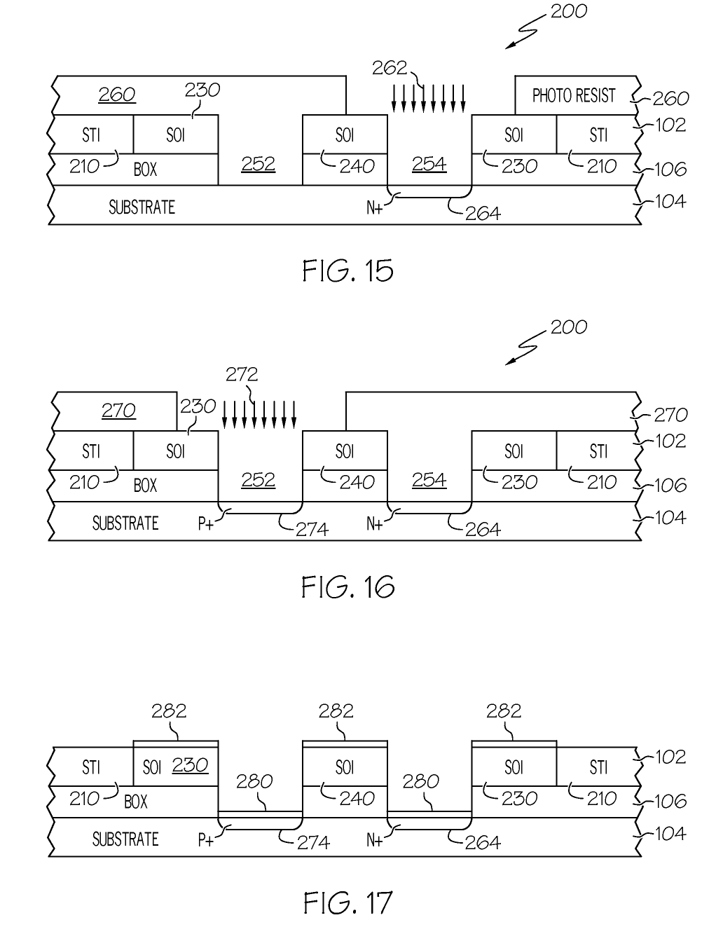

The method continues, in accordance with this alternate embodiment of the disclosure, by removing patterned photoresist layer 250 and by applying and patterning a photoresist layer 260 to expose opening 254 while masking opening 252 as shown in FIG. 15. Patterned photoresist layer 260 is used as an ion implantation mask and N-type impurity dopant ions, preferably arsenic ions, are implanted into the exposed areas as indicated by arrows 262. The N-type impurity dopant ions form N-doped region 264 that is self aligned within the semiconductor structure 200. The extent of N-doped region 264 is determined by the spacing between SOI regions 240, 230 of the SOI substrate layer 102.

After removing patterned photoresist layer 260, the method for fabricating the semiconductor structure 200 continues as illustrated in FIG. 16 by the application and patterning of an additional photoresist layer 270. Photoresist layer 270 is patterned to expose opening 252 while masking opening 254. Patterned photoresist layer 270 is used as an ion implantation mask and P-type impurity dopant ions, preferably boron ions, are implanted into the exposed areas as indicated by arrows 272. The P-type impurity dopant ions form P-doped region 274 that is self aligned with the N-doped region 264 within the semiconductor structure 200.

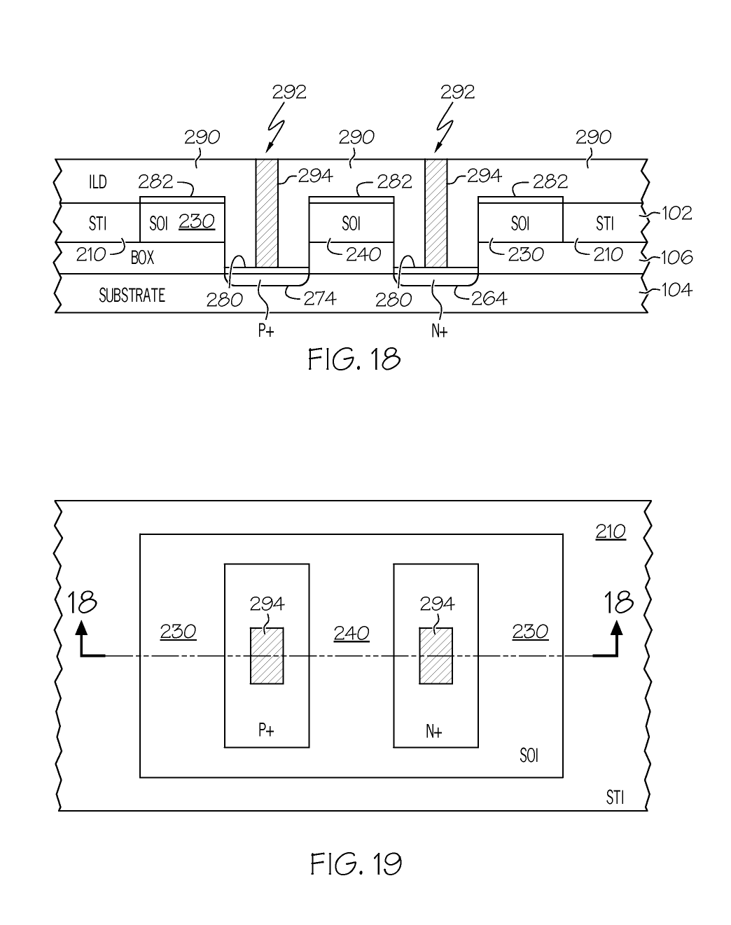

Referring to FIG. 17, the semiconductor structure 200 can be completed in the same manner as semiconductor diode device 100, by forming metal silicide regions 280 above the P-doped region 274 and the N-doped region 264, as well as metal silicide regions 282 above the SOI regions 230, 240. Metal such as nickel, cobalt, titanium, palladium, or the like is deposited to provide a metal layer which, when heated, forms the metal silicide regions 280. Referring to FIG. 18, ILD material is deposited and planarized to form the ILD layer 290 in the same manner as described above. Contact openings 292 are then etched through the ILD material 290 and conductive plugs 294 are formed therein to provide contacts to the metal silicide layers 280.

While FIG. 18 depicts a cross section view of the semiconductor structure 200, FIG. 19 illustrates a plan view of the structure 200. Referring to FIG. 19, the semiconductor structure 200 includes the SOI ring structure 230 with the SOI divider 240 splitting the area enclosed within the SOI ring structure 230. The two regions surrounded by SOI material 230, 240 are the P-doped region 274 and the N-doped region 264 covered by the ILD material 290 with the contacts 294 providing connection from regions 264, 274 through the ILD material 290.

While at least one exemplary embodiment has been presented in the foregoing detailed description of the invention, it should be appreciated that a vast number of variations exist. It should also be appreciated that the exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

What is claimed is:

1. A method for fabricating a semiconductor component including a semiconductor on insulator (SOI) substrate, the semiconductor component having a first semiconductor layer, a layer of insulator material on the first semiconductor layer and the SOI substrate comprised of a layer of SOI material on the layer of insulator material, the method comprising the steps of:
etching at least a first opening and a second opening extending through the SOI substrate to remove a first portion and a second portion of the SOI material and expose portions of the layer of insulator material;
filling the at least first and second openings with a shallow trench isolation (STI) material;
etching at least a third opening and a fourth opening extending through the SOI substrate and the layer of insulator material, the third and fourth openings defined by remaining SOI material in the SOI substrate and etching away the STI material in the SOI substrate.

2. The method in accordance with claim 1 further comprising the step of chemical mechanical polishing (CMP) the STI material and the remaining SOI material after the step of filling the at least first and second openings with the STI material.

3. The method of claim 1 wherein the step of etching at least the third and fourth openings comprises the steps of:
depositing a layer of photoresist overlying the SOI substrate;
patterning the layer of photoresist to form a photoresist mask comprising at least a first mask region;
etching at least the third opening and the fourth opening within an area defined by the first mask region, each of the third opening and the fourth opening extending through the SOI substrate and the layer of insulator material and defined by the remaining SOI material of the SOI substrate.

4. The method in accordance with claim 1 further comprising the steps of:
implanting first type conductivity determining ions into the first semiconductor layer through the third opening to form a first impurity doped region of a first conductivity type in the first semiconductor layer;
implanting second type conductivity determining ions into the first semiconductor layer through the fourth opening to form a second impurity doped region of a second conductivity type in the first semiconductor layer; and
forming a first electrical contact to the first impurity doped region and a second electrical contact to the second impurity doped region.

5. The method in accordance with claim 4 further comprising, after the steps of implanting the first and second type conductivity determining ions, the step of depositing dielectric material within the area defined by the first mask region to form an interlayer dielectric (ILD) layer on the SOI substrate and to fill the third and fourth openings with the dielectric material.

6. The method in accordance with claim 5 further comprising the step of depositing conductive material within the third and fourth openings to form a silicide layer over the first and second impurity doped regions, respectively, prior to the step of depositing the dielectric material, and wherein the step of forming the first and second electrical contacts comprises the step of forming the first electrical contact to the silicide layer over the first impurity doped region and the second electrical contact to the silicide layer over the second impurity doped region.

7. The method in accordance with claim 1 wherein the step of etching at least the first opening and the second opening extending through the SOI substrate comprises the step of etching the SOI substrate to form at least two concentric SOI rings.

8. The method in accordance with claim 7 wherein the step of etching the SOI substrate to form at least two concentric SOI rings comprises the step of etching the first opening as a ring structure and etching the second opening as a structure encircled by the first ring structure and separated therefrom by a portion of the SOI substrate that is not etched which forms an inside one of the two concentric SOI rings.

9. The method in accordance with claim 5 further comprising the step of deep implanting the first type of conductivity determining ions into the first semiconductor layer within the area defined by the first mask region to form a lightly doped well region of the first conductivity type in the first semiconductor layer after the step of patterning the layer of photoresist to form the photoresist mask.

10. The method in accordance with claim 9 wherein the first substrate layer comprises a p-type silicon layer, and wherein the first type conductivity determining ions comprise n-type conductivity determining ions, and wherein the second type conductivity determining ions comprise p-type conductivity determining ions.

11. The method of claim 1 wherein the step of etching at least a third opening and a fourth opening comprises the step of etching the SOI substrate and the layer of insulator material to form at least one structure area therein having at least one divider dividing the structure area into at least a first region defined by the SOI material and a second region defined by the SOI material.

12. A method for fabricating a semiconductor diode structure comprising the steps of:
providing a semiconductor structure having a first semiconductor layer, a layer of insulator material on the first semiconductor layer and a semiconductor on insulator (SOI) substrate comprised of a layer of SOI material on the layer of insulator material;
etching a first opening forming a first ring structure extending through the SOI substrate and a second opening forming a second ring structure extending through the SOI substrate to remove a first portion and a second portion, respectively, of the SOI material and expose portions of the layer of insulator material, wherein the first ring structure encircles the second ring structure and is separated therefrom by a ring structure portion of the SOI substrate that is not etched;
filling the at least first and second openings with a shallow trench isolation (STI) material;
depositing a layer of photoresist overlying the SOI substrate;
patterning the layer of photoresist to form a photoresist mask comprising a first mask region;
deep implanting a first type conductivity determining ions into the first semiconductor layer within the area defined by the first mask region to form a lightly doped well region of a first conductivity type in the first semiconductor layer;
depositing a layer of photoresist overlying the SOI substrate;
patterning the layer of photoresist to form a photoresist mask comprising a second mask region smaller than the first mask region;
etching at least a third opening and a fourth opening within an area defined by the second mask region, each of the third opening and the fourth opening extending through the SOI substrate and the layer of insulator material and the third and fourth openings defined by the SOI material and etching away the STI material;
implanting the first type conductivity determining ions into the first semiconductor layer through the third opening to form a first impurity doped region of the first conductivity type in the first semiconductor layer;
implanting second type conductivity determining ions into the first semiconductor layer through the fourth opening to form a second impurity doped region of a second conductivity type in the first semiconductor layer; and
forming a first electrical contact to the first impurity doped region and a second electrical contact to the second impurity doped region.

13. The method in accordance with claim 12 wherein the first substrate layer comprises a p-type silicon layer, and wherein the first type conductivity determining ions comprise n-type conductivity determining ions, and wherein the second type conductivity determining ions comprise p-type conductivity determining ions.

14. The method in accordance with claim 12 further comprising the step of chemical mechanical polishing (CMP) the STI material and the SOI material after the step of filling the at least first and second openings with the STI material.

15. The method in accordance with claim 12 further comprising, after the steps of implanting the first and second type conductivity determining ions, the step of depositing dielectric material within the area defined by the first mask region to form an interlayer dielectric (ILD) layer on the SOI substrate and to fill the third and fourth openings with the dielectric material.

16. The method in accordance with claim 14 further comprising the step of depositing conductive material within the third and fourth openings to form a silicide layer over the first and second impurity doped regions, respectively, prior to the step of depositing the dielectric material, and wherein the step of forming the first and second electrical contacts comprises the step of forming the first electrical contact to the silicide layer over the first impurity doped region and the second electrical contact to the silicide layer over the second impurity doped region.

17. A method for fabricating a semiconductor structure comprising the steps of:
providing a semiconductor structure having a first semiconductor layer, a layer of insulator material on the first semiconductor layer and a semiconductor on insulator (SOI) substrate comprised of a layer of SOI material on the layer of insulator material;
etching at least a first opening and a second opening extending through the SOI substrate to remove a first portion and a second portion of the SOI material and expose portions of the layer of insulator material;
filling the at least first and second openings with a shallow trench isolation (STI) material;
depositing a layer of photoresist overlying the SOI substrate;
patterning the layer of photoresist to form a mask comprising at least a first mask region;
etching the SOI substrate and the layer of insulator material to form a structure area corresponding to the semiconductor structure therein, the structure area having at least one SOI divider dividing the structure area into at least a third opening defined by the SOI material and a fourth opening defined by the SOI material, each of the third opening and the fourth opening extending through the SOI substrate and the layer of insulator material and the third and fourth openings defined by the SOI material and etching away the STI material in the SOI semiconductor layer;
implanting first type conductivity determining ions into the first semiconductor layer through the third opening to form a first impurity doped region of a first conductivity type in the first semiconductor layer;
implanting second type conductivity determining ions into the first semiconductor layer through the fourth opening to form a second impurity doped region of a second conductivity type in the first semiconductor layer; and
forming a first electrical contact to the first impurity doped region and a second electrical contact to the second impurity doped region.

18. The method in accordance with claim 17 further comprising, after the steps of implanting the first and second type conductivity determining ions, the step of depositing dielectric material within the area defined by the first mask region to form an interlayer dielectric (ILD) layer on the SOI substrate and to fill the third and fourth openings with the dielectric material.

19. The method in accordance with claim 18 wherein the step of forming the first and second electrical contacts comprises the steps of:
depositing a layer of photoresist overlying the ILD layer;
patterning the layer of photoresist to form a photoresist mask comprising at least a second mask region within an area defined by the third opening and a third mask region within an area defined by the fourth opening;
etching at least a fifth opening defined by the second mask region and a sixth opening defined by the third mask region, each of the fifth opening and the sixth opening extending through the ILD layer and the dielectric material within the third and fourth openings, respectively, and etching away the dielectric material; and
forming the first electrical contact through the fifth opening to the first impurity doped region and the second electrical contact through the sixth opening to the second impurity doped region.

20. The method in accordance with claim 18 further comprising the step of depositing conductive material within the third and fourth openings to form a silicide layer over the first and second impurity doped regions, respectively, prior to the step of depositing the dielectric material, and wherein the step of forming the first and second electrical contacts comprises the step of forming the first electrical contact to the silicide layer over the first impurity doped region and the second electrical contact to the silicide layer over the second impurity doped region.
